(19) United States
(12) Patent Application Publication
(10) Pub. No.: US 2007/0178863 A1
(43) Pub. Date: Aug. 2, 2007

(54) AM/FM tuner saw filter-less architecture using AM frequency band up-conversion

(76) Inventors: G. Tyson Tuttle, Austin, TX (US); Dan B. Kasha, Seattle, WA (US)

Correspondence Address: O'KEEFE, EGAN, PETERMAN & ENDERS LLP, 1101 CAPITAL OF TEXAS HIGHWAY SOUTH, #C200, AUSTIN, TX, 78746, US

(21) Appl. No.: 11/471,917

(22) Filed: Jun. 21, 2006

Related U.S. Application Data
(60) Provisional application No. 60/762,812, filed on Jan. 27, 2006.

(51) Int. Cl. H03D 5/00

(52) U.S. Cl. 455/142

(57) ABSTRACT

A receiver for AM and FM broadcast signals is disclosed. FM signals are received from an FM antenna and then processed by receive path circuitry or an FM tuner integrated circuit (IC) to produce audio output signals, such as digital audio output signals. The AM signals are received by an AM antenna and then up-converted using a fixed-clock to a frequency range nearer to the FM signal frequencies. The up-converted AM frequencies are then processed using the receive path circuitry. A multiplexer (MUX) allows for selection of the FM signals or the up-converted AM signals to be passed through for signal processing.

### RELATED APPLICATIONS

This application claims priority to the following co-pending provisional application: Provisional Application Ser. No. 60/762,912, which was entitled “AM/FM TUNER SAW FILTER-LESS ARCHITECTURE USING AM FREQUENCY BAND UP-CONVERSION” and was filed on Jan. 27, 2006.

### TECHNICAL FIELD OF THE INVENTION

This invention relates to receiver architectures for radio-frequency communications. More particularly, the present invention relates to audio broadcast receivers.

### BACKGROUND

Radio frequency (RF) receivers are used in a wide variety of applications such as television, cellular telephones, pagers, global positioning system (GPS) receivers, cable modems, cordless phones, radios and other devices that receive RF signals. RF receivers typically require frequency translation or mixing. For example, with respect to FM or AM audio broadcasts, radio receivers may translate a broadcast channel within the FM or AM frequency band to an intermediate frequency that can be further processed to produce audio output signals.

Although AM receiver architectures and FM receiver architectures have long existed, difficulties arise when attempting to receive both AM and FM signals within the same receiver architecture. In particular, there is a need for cost efficient AM/FM receiver that is suitable for the portable device environment.

### SUMMARY OF THE INVENTION

The present invention is a receiver for AM and FM broadcast signals. FM signals are received from an FM antenna and then processed by receive path circuitry or an FM tuner integrated circuit (IC) to produce audio output signals, such as digital audio output signals. The AM signals are received by an AM antenna and then up-converted using a fixed-clock to a frequency range nearer to the FM signal frequencies. The up-converted AM frequencies are then processed using the receive path circuitry. A multiplexer (MUX) allows for selection of the FM signals or the up-converted AM signals to be passed through for signal processing.

### DESCRIPTION OF THE DRAWINGS

It is noted that the appended drawings illustrate only exemplary embodiments of the invention and are, therefore, not to be considered limiting of its scope, for the invention may admit to other equally effective embodiments.

FIG. 1 is a block diagram for an embodiment of the present invention where an FM tuner IC, an external MCU IC and a fixed-clock mixer are utilized.

FIG. 2 is a block diagram for an embodiment of the present invention where an integrated AM/FM receiver is utilized that includes receive path circuitry, an on-chip MCU, and an on-chip mixer.

### DETAILED DESCRIPTION OF THE INVENTION

The present invention provides a terrestrial audio broadcast receiver and associated method for receiving AM/FM broadcast signals.

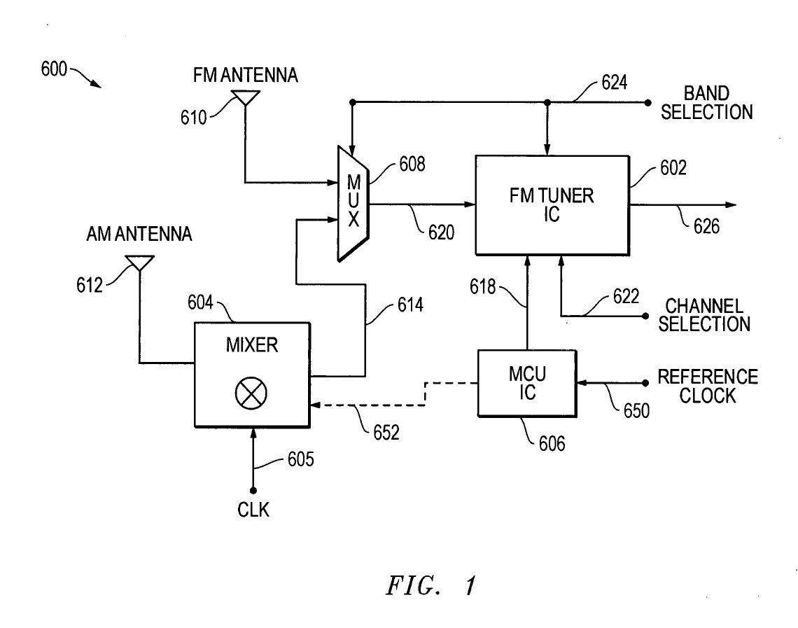

FIG. 1 is a block diagram of an embodiment 600 for the present invention. The embodiment 600 includes a multiplexer (MUX) 608, an FM tuner IC 602, an MCU IC 606 and a mixer 604. The mixer 604 utilizes a fixed clock input (CLK) 605. The fixed clock input (CLK) 605 can also be generated as desired. For example, the fixed input clock input (CLK) 605 can be provided from the MCU, from an external clock source, from an external crystal oscillator, or from other clock generation circuitry, as desired. The fixed clock input (CLK) 605 can be any desired frequency and can be, for example, a frequency above about 40 MHz (e.g., 40 MHz, 50 MHz, 55 MHz, 60 MHz, etc.). While the fixed clock input (CLK) 605 can take on multiple values, in operation, it remains fixed and does not accomplish the fine tuning of the incoming signals. This tuning is accomplished within the FM tuner IC 602 which can be designed to be well suited for such a task.

In operation, FM broadcast signals are received through an FM antenna 610 and provided to the MUX 608. If the band selection signal 624 has selected FM reception, the MUX 608 passes the signals from the FM antenna 610 to the FM tuner IC 602 through signal path 620. The FM tuner IC 602 then processes the FM signals based upon the channel selection signal 622 to tune and output audio signals 626 according to the content broadcast on the selected channel. The audio output signals 626 can be, for example, left and right digital audio signals.

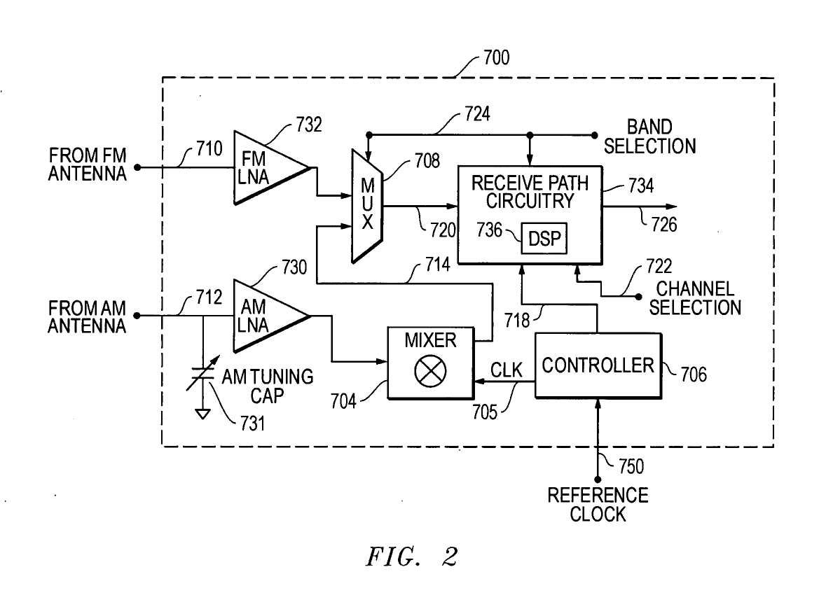

AM broadcast signals are received through an AM antenna 612 and provided to the mixer 604. If desired, one or more input LNAs (low noise amplifiers) could be utilized to process signals from the FM antenna 610 and the AM antenna 612. The mixer mixes the AM signals with a fixed clock (CLK) 605 (which again can be a clock signal from MCU 606) to up-convert the AM signals to a frequency range nearer to the FM signal spectrum. For example, a clock of about 50 MHz can be used for the fixed clock (CLK) 605 to move the AM frequency band to frequencies closer to or within the FM frequency band. The output of the mixer 604 is provided to the MUX 608. If the band selection signal 624 has selected AM reception, the MUX 608 passes the signals 614 from the mixer 604 to the FM tuner IC 602 through signal path 620. Preferably, as depicted in the example embodiments of FIG. 1 and FIG. 2, a surface-acoustic-wave (SAW) filter is not utilized to filter the AM signals.

The FM tuner IC 602 then processes the AM signals based upon the channel selection signal 622 to tune and output audio signals 626 according to the content broadcast on the selected channel. For this AM signal processing, an external MCU IC 606 can provide the algorithms needed to convert the FM tuner IC 602 to a suitable tuner for the AM reception. These algorithms could be used, for example, to provide new filter responses, new detector algorithms, new tuning algorithms and new AGC (automatic gain control) algorithms, etc., as desired. The MCU IC 606 alternatively could help with some of this processing directly as opposed to transferring algorithms to the FM Tuner IC 602 for operation on the FM Tuner IC 602. For AM channels, the audio output signals 626 can be, for example, mono digital audio signals or stereo digital audio signals.

With respect to the clock signals in the embodiment 600 of FIG. 1, in one implementation a fixed clock could be used where the clock signal is provided from a crystal oscillator or some other source to do the AM frequency band up-conversion. In contrast with a variable frequency mixing signal that would always put the tuned signal at some designated IF frequency, this AM band up-conversion of the present invention moves the AM channels frequency band up to a higher frequency range using a fixed frequency mixing signal. With this fixed-clock scheme, the AM band is simply shifted up by a fixed amount. The following receiver then is tuned to the desired frequency to select a particular channel. Alternatively, the MCU 606 can provide the clock signal as well, as it gets a reference clock 650 as well for its operations, which can be used to derive a suitable clock for the up-conversion. As such, the mixing clock input signal (CLK) 605 can be a clock from the MCU 606 for the up-conversion, as represented by dotted line 652, or it can be a clock signal from some other source, as indicated above. The clock reference signal 650, for example, from a crystal oscillator, can be used to feed a reference clock signal to the MCU 606. This reference clock signal 650 can also be used to provide a reference clock signal to the FM Tuner IC 602, to the mixer 604 and/or to any other desired circuitry. In other words, there can be a single clock source utilized in the system or multiple clock sources utilized in the system, depending upon the desired implementation.

The MCU 606 also provides a second role. It can be programmed to contain the code that is utilized by the FM tuner IC 602 and digital signal processing (DSP) circuitry with the FM tuner IC 602 to run in AM mode in a circumstance where the FM Tuner IC 602 does not have enough memory to hold the entire AM and FM code. As such, in AM mode, the AM code can be downloaded to the FM tuner IC 602 using the external MCU. The AM code contains the frequency tuning algorithms for AM processing, the AM detector, the AGC code required for AM, and the channel selection filter, and may contain code for other functionality, as desired. The code and control signals from the MCU 606 can be transferred to the FM tuner IC 602 through communication signals 618.

FIG. 2 is a block diagram of an integrated embodiment 700 for the present invention. The integrated embodiment 700 includes a multiplexer (MUX) 708, a receive path circuitry 734, an integrated MCU or controller 706 and a mixer 704. The mixer 704 utilizes a fixed clock input (CLK) 705 that can be provided, for example, from the an on-chip MCU or controller 706, which in turn receives an external reference clock signal 750. It is noted that the fixed clock signal 705 could also be generated on-chip, for example, using an output signal or a divided or multiplied version of an output signal from an on-chip oscillator such as the local oscillator (LO) used for mixing. As noted above, the reference clock signal 750 can also be utilized to provide clock signals to other on-chip circuitry, as desired.

In operation, FM broadcast signals 710 are received through an FM antenna and provided through an FM low noise amplifier (LNA) 732 to the MUX 708. It is noted that the FM LNA 732 may or may not be utilized. If the band selection signal 724 has selected FM reception, the MUX 708 passes the FM signals to, the receive path circuitry 734 through signal path 720. The receive path circuitry 734 including DSP circuitry 736 then processes the FM signals based upon the channel selection signal 722 to tune and output audio signals 726 according to the content broadcast on the selected channel. The audio output signals 726 can be, for example, left and right digital audio signals.

AM broadcast signals 712 are received through an AM antenna and provided through AM LNA 730 to the mixer 704. It is noted that the AM LNA 730 may or may not be utilized and could be combined with the mixer 704 itself, if desired. In addition, if desired, an on-chip AM tuning capacitor or tunable capacitor array 731 can be utilized to help filter the incoming AM signal. This AM tuning capacitor 731 can be controlled by the MCU or controller 706. The mixer mixes the AM signals with a fixed clock (CLK) 705 to up-convert the AM signals to a frequency range nearer to the FM signal spectrum. For example, a 50 MHz clock can be used for the fixed clock (CLK) 705. The output of the mixer 704 is provided to the MUX 708. If the band selection signal 724 has selected AM reception, the MUX 708 passes the output signals 714 from the mixer 704 to the receive path circuitry 734 through signal path 720. As indicated above, the AM signals 714 are an up-converted version of the AM broadcast signals. For example, the AM frequency band can be mixed up to a frequency band within or near the FM frequency band. The FM tuner IC 702 then processes the AM signals based upon the channel selection signal 722 to tune and output audio signals 726 according to the content broadcast on the selected channel. For AM channels, the audio output signals 726 can be, for example, mono digital audio signals or stereo digital audio signals.

It is noted that a wide variety of implementations could be utilized with respect to the clock signals in the embodiment 700 of FIG. 2. Similar to embodiment 600 of FIG. 1, the fixed clock signal (CLK) 605 can come from a variety of sources. Because embodiment 700 relates to a single integrated IC implementation, the clock signal could be provided from a single external reference clock that is also used by other on-chip circuitry, such as controller circuitry 706 and the receive path circuitry 734. This external reference clock signal may be processed by clock control circuitry or other processing before use by the various on-chip circuits. For example, an external reference clock 750 could be fed in to the controller 706 for processing and distribution to the mixer 704 as fixed clock signal (CLK) 705. The controller 706 could also generate other reference clock signals for use by the receive path circuitry 734 or other circuitry on the integrated IC 700. As such, the controller 706 would make clock signals that are fed to the receive path circuitry 734 and to the mixer 705. It is noted that there are other ways to accomplish the distribution of clock signals. For example, the external reference clock 750 could go directly into the up-conversion mixer 704, through a simple divider and then to the mixer 704, or to other clock processing circuitry, as desired.

In addition to distributing clock signals, the MCU or controller 706 in the embodiment 700 can also provide other control functions. For example, the controller 706 can perform functions needed for receiving and processing FM broadcast signals including controlling memory operations, processing clock signals, operating calibration algorithms, etc. The controller 706 can perform functions needed for receiving and processing AM broadcast signals. As such, the controller 706 can provide the control signals for setting the MUX 708, for having the right processing algorithms set for the receive path circuitry 734, for clocking the up-conversion mixer, and for any other desired control functionality. The code and control signals from the MCU or controller 706 can be transferred to the receive path circuitry 734 through communication signals 718.

Further modifications and alternative embodiments of this invention will be apparent to those skilled in the art in view of this description. It will be recognized, therefore, that the present invention is not limited by these example arrangements. Accordingly, this description is to be construed as illustrative only and is for the purpose of teaching those skilled in the art the manner of carrying out the invention. It is to be understood that the forms of the invention herein shown and described are to be taken as the presently preferred embodiments. Various changes may be made in the implementations and architectures. For example, equivalent elements may be substituted for those illustrated and described herein, and certain features of the invention may be utilized independently of the use of other features, all as would be apparent to one skilled in the art after having the benefit of this description of the invention.

What is claimed is:

1. An AM/FM receiver using AM frequency band up-conversion, comprising:
a mixer coupled to mix an input AM signal from an AM antenna with a fixed clock signal to generate an up-converted AM signal;
a multiplexer coupled to receive an input FM signal from an FM antenna and the up-converted AM signal, the multiplexer being configured to receive a band selection signal that determines whether the up-converted AM signal or the FM signal is output by the multiplexer; and
receive path circuitry configured to receiver the output of the multiplexer, configured to tune an AM channel within the up-converted AM signal if the band selection signal has selected the up-converted AM signal, and configured to tune an FM channel within the FM signal if the band selection signal has selected the FM signal.

2. The AM/FM receiver of claim 1, wherein an surface-acoustic-wave (SAW) filter is not utilized to filter the AM signals.

3. The AM/FM receiver of claim 1, wherein the mixer, the multiplexer and the receive path circuitry are integrated within a single integrated circuit.

4. The AM/FM receiver of claim 3, wherein the receive path circuitry comprises a digital signal processor (DSP) configured to provide AM processing and FM processing.

5. The AM/FM receiver of claim 4, further comprising controller circuitry coupled to the receive path circuitry and configured to provide control signals for the digital signal processor (DSP).

6. The AM/FM receiver of claim 5, wherein the controller circuitry is configured to receive a reference clock and configured to output the fixed clock signal to the mixer.

7. The AM/FM receiver of claim 6, wherein the controller circuitry is integrated within the single integrated circuit.

8. The AM/FM receiver of claim 1, wherein the fixed clock signal comprises a frequency above about 40 MHz.

9. The AM/FM receiver of claim 8, wherein the fixed clock signal is about 50 MHz.

10. The AM/FM receiver of claim 1, further comprising a variable capacitance coupled to filter the input AM signal, the variable capacitance being integrated on the single integrated circuit.

11. A method for receiving AM and FM signals using AM frequency band up-conversion, comprising:
receiving an input AM signal and an input FM signal;
selecting to process the input AM signal using AM processing or to process the input FM signal using FM processing;
if FM processing is selected, tuning an FM channel within the FM signal; and
if AM processing is selected, first mixing the input AM signal with a fixed clock signal to generate an up-converted AM signal and then tuning an AM channel within the up-converted AM signal.

12. The method of claim 11, wherein an surface-acoustic-wave (SAW) filter is not utilized to filter the AM signals.

13. The method of claim 1, further comprising performing the selecting, tuning an FM channel and tuning an AM channel steps within a single integrated circuit.

14. The method of claim 13, further comprising utilizing a digital signal processor (DSP) to provide the AM processing and the FM processing.

15. The method claim 14, further utilizing controller circuitry to provide control signals for the digital signal processor (DSP).

16. The method claim 15, further comprising further utilizing the controller circuitry to receive a reference clock signal and to output the fixed clock signal.

17. The method claim 16, further comprising performing the utilizing steps within the single integrated circuit.

18. The method of claim 11, further comprising providing a frequency above about 40 MHz as the fixed clock signal.

19. The method of claim 18, wherein the fixed clock signal is about 50 MHz.

20. The method of claim 11, further filtering the input AM signal with variable capacitance circuitry and performing the filtering step within the single integrated circuit.
